(19) United States
(12) Patent Application Publication
(10) Pub. No.: US 2025/0183088 A1
(43) Pub. Date: Jun. 5, 2025

(54) METHOD FOR REMOVING RESIDUES FROM A SUBSTRATE SURFACE

(71) Applicant: IMEC VZW, Leuven (BE)

(72) Inventors: Efrain Altamirano Sanchez, Kessel-Lo (BE); Quoc Toan Le, Belgrade (BE)

(21) Appl. No.: 18/960,434

(22) Filed: Nov. 26, 2024

(30) Foreign Application Priority Data
Dec. 1, 2023 (EP) 23213742.2

(51) Int. Cl. H01L 21/683; H01L 21/02; H01L 23/00

(52) U.S. Cl. CPC H01L 21/6835; H01L 21/02118; H01L 21/02167; H01L 24/05; H01L 24/06; H01L 24/08; H01L 2221/68318; H01L 2224/0555; H01L 2224/05647; H01L 2224/06131; H01L 2224/08145; H01L 2924/35

(57) ABSTRACT

The disclosure is related to removing a temporary polymer bonding layer from a dielectric or hybrid bonding surface of a process wafer including a plurality of dies which are to be bonded to other dies or to a substrate by hybrid bonding or direct dielectric-to-dielectric bonding. Producing an auxiliary layer precedes the production of the polymer bonding layer on the die side of the wafer, e.g. on the bonding surfaces of the dies. According to the disclosure, the auxiliary layer is formed of a nitride or a carbide of a transition metal, for example titanium nitride or tungsten carbide. These materials enable removing the auxiliary layer including any polymer residue, without negatively affecting the dielectric or hybrid dielectric and/or metal bonding surfaces of the dies.

### CROSS-REFERENCE TO RELATED APPLICATIONS

The present application is a non-provisional patent application claiming priority to European Patent Application No. 23213742.2, filed Dec. 1, 2023, the contents of which are hereby incorporated by reference.

### FIELD OF THE DISCLOSURE

The present disclosure is related to semiconductor processing, and in particular to cleaning steps applied at various stages during a semiconductor fabrication process.

### BACKGROUND

Semiconductor processing utilizes different types of polymers. Two applications of polymer layers are used as photoresists (PR) layers, primarily deep ultraviolet (DUV) photoresist layers, and layers of temporary bonding material (TBM). The nature and thickness of such polymer layers vary depending on the types of DUV PRs, ranging from 1 μm to about 150 μm in thickness, and TBMs, either thermoplastic or elastomer types with thicknesses ranging from 1 μm to about 100 μm. These polymers may be coated on target 300 mm wafers for different purposes, such as lithography, temporary bonding between target and carrier wafers, protective layers for singulation, or the like. Such polymers are sacrificial and may be stripped before performing subsequent steps, for example before hybrid bonding between metal-metal (e.g. Cu—Cu, Al—Al) and dielectric-dielectric (e.g. SiO₂—SiO₂, SiCN—SiCN, SiN—SiN). The stripping of such polymers is carried out using one or more organic solvents or aqueous chemicals, but polymer residues are likely to remain on the surface after these stripping procedures. When such residues remain on a bonding surface for hybrid bonding or direct dielectric-to-dielectric bonding, for example, they can be responsible for the creation of micro-voids in the bonding region.

Such residues are however challenging to remove without attacking the surface. For example, when the surface is a hybrid bonding surface, including a dielectric material with metal contact pads coplanar therewith, applicable chemistries for the removal of a temporary bonding layer from such a surface are subject to narrowly defined conditions in order to avoid damage to the metal and/or the dielectric. Under such conditions, polymer residue may remain on the surface. The stripping of the polymers can also induce a surface modification of the metal that may manifest as corrosion in downstream integration steps.

To address these problems, the provision of a sacrificial layer on the surface may be provided before producing the polymer layer directly on the sacrificial layer and stripping the polymer relative to the sacrificial layer may be provided, so that the polymer residues remain on the sacrificial layer. Removing the sacrificial layer also removes the polymer residues. Patent publication documents EP3563411 and EP1936678 describe methods in the context of dielectric-to-dielectric or hybrid bonding methods. In these documents, sacrificial layers are cited which are formed of silicon oxide, aluminium or titanium. These materials are however not able to address the low roughness and planarity of the bonding layers in present-day bonding technologies. This is because the removal of these materials may cause roughening of dielectric bonding layers and/or oxidation of metal pads in a hybrid bonding surface.

### SUMMARY

The disclosure is related to a method as disclosed in the appended claims.

According to the disclosure, a temporary polymer layer on a substrate in a semiconductor processing sequence is produced on an auxiliary layer produced on the substrate prior to forming the temporary polymer layer. The auxiliary layer is removable from the surface of the substrate (e.g., essentially) without leaving residues on the surface. The polymer layer and the auxiliary layer are removed after a number of processing steps performed on the substrate. The removal of the polymer layer may leave residue on the auxiliary layer, but removing the latter leaves the surface (e.g., essentially) residue-free. The disclosure is also related to removing a temporary polymer bonding layer from a dielectric or hybrid bonding surface of a process wafer including a plurality of dies which are to be bonded to other dies or to a substrate by hybrid bonding or direct dielectric-to-dielectric bonding. Producing the auxiliary layer precedes the production of the polymer bonding layer on the die side of the wafer, e.g. on the bonding surfaces of the dies. According to the disclosure, the auxiliary layer is formed of a nitride or a carbide of a transition metal, for example titanium nitride or tungsten carbide. These materials enable removing the auxiliary layer including any polymer residue, without (e.g., negatively) affecting the dielectric or hybrid dielectric/metal bonding surfaces of the dies. The disclosure thereby enables the removal of temporary bonding material from a dielectric or hybrid bonding surface (e.g., essentially) without leaving polymer residue, so that the appearance of voids during hybrid bonding or dielectric-to-dielectric bonding is avoided and without increasing the roughness of the dielectric bonding surfaces or oxidizing metal areas in the bonding surfaces.

The disclosure is (e.g., generically) related to a semiconductor processing method including a coating step wherein a temporary polymer layer is produced on a substrate, and further including, after the coating step and after executing one or more further processing steps on the substrate, a removal step wherein the temporary layer is removed or wherein parts of the layer are removed which have remained after executing the one or more further processing steps. Directly prior to the coating step, an auxiliary layer is produced (e.g., directly) on a surface of the substrate, the auxiliary layer being removable from the surface (e.g., essentially) without leaving any residues on the surface, such that the temporary polymer layer is produced directly on the auxiliary layer. The removal step includes removing the temporary polymer layer or the parts thereof, selectively with respect to the auxiliary layer, and/or removing (e.g., or essentially removing) the auxiliary layer, selectively with respect to the surface of the substrate, resulting in a substantially residue-free substrate surface. The wording ‘removing or essentially removing’ encompasses both the complete removal of the polymer or the removal of the majority of the polymer with only a small amount remaining, for example in the form of polymer residue.

In some embodiments, the method according to the disclosure includes providing the substrate in the form of a process wafer including a die side and a back side and including on the die side a plurality of dies which include a bonding surface suitable for direct dielectric-to-dielectric or hybrid bonding of the dies to a target substrate. The method further includes (e.g., thereafter) producing the auxiliary layer directly on the bonding surfaces of the dies (e.g. ‘a surface of the substrate’), the auxiliary layer being removable from the bonding surfaces (e.g., essentially) without leaving any residues on the bonding surfaces. The method also includes (e.g., thereafter) producing the temporary polymer layer in the form of a temporary polymer bonding layer directly on the auxiliary layer. The method yet further includes (e.g., thereafter) temporarily bonding the process wafer to a carrier substrate by removably attaching the temporary bonding layer to the carrier substrate, performing processing steps on the back side of the process wafer, and releasing the process wafer from the carrier substrate so that the auxiliary layer and the temporary bonding layer remain on the die side of the process wafer. The method also includes (e.g., thereafter) removing (e.g., or essentially removing) the temporary polymer layer, selectively with respect to the auxiliary layer. The method further includes (e.g. thereafter) removing the auxiliary layer, selectively with respect to the bonding surfaces, resulting in substantially residue-free bonding surfaces, wherein the auxiliary layer is formed of a nitride or a carbide of a transition metal.

According to embodiments of the disclosure, the auxiliary layer is formed of a material chosen from the group consisting of: titanium nitride, hafnium nitride, tungsten nitride, molybdenum nitride, tungsten carbide.

According to an embodiment, the bonding surfaces of the dies are suitable for hybrid bonding, including metal contact pads embedded in a layer of dielectric material.

According to an embodiment, the metal contacts are Cu contact pads and wherein the layer of dielectric material is a layer of SiCN.

According to an embodiment, the temporary polymer bonding layer is removed (e.g., or essentially removed) by applying a solvent to the polymer layer.

According to an embodiment, after removing the temporary polymer bonding layer or the parts thereof selectively with respect to the auxiliary layer, residues of the polymer layer remain on the auxiliary layer.

According to an embodiment, the auxiliary layer is removed by wet etching.

According to an embodiment, the thickness of the auxiliary layer is between 5 nm and 100 nm.

### BRIEF DESCRIPTION OF THE FIGURES

The above, as well as additional, features will be better understood through the following illustrative and non-limiting detailed description of example embodiments, with reference to the appended drawings.

FIGS. 1a, 1b, and 1c illustrate a process wafer and a layout of multiple dies on the wafer.

FIGS. 2, 3, 4, 5, 6, 7, 8, and 9 illustrate method steps which illustrate an exemplary embodiment of the disclosure.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

The disclosure will be described on the basis of an exemplary embodiment, which is however not limiting the scope of the disclosure. All references with respect to shapes, dimensions or materials are cited by way of example only.

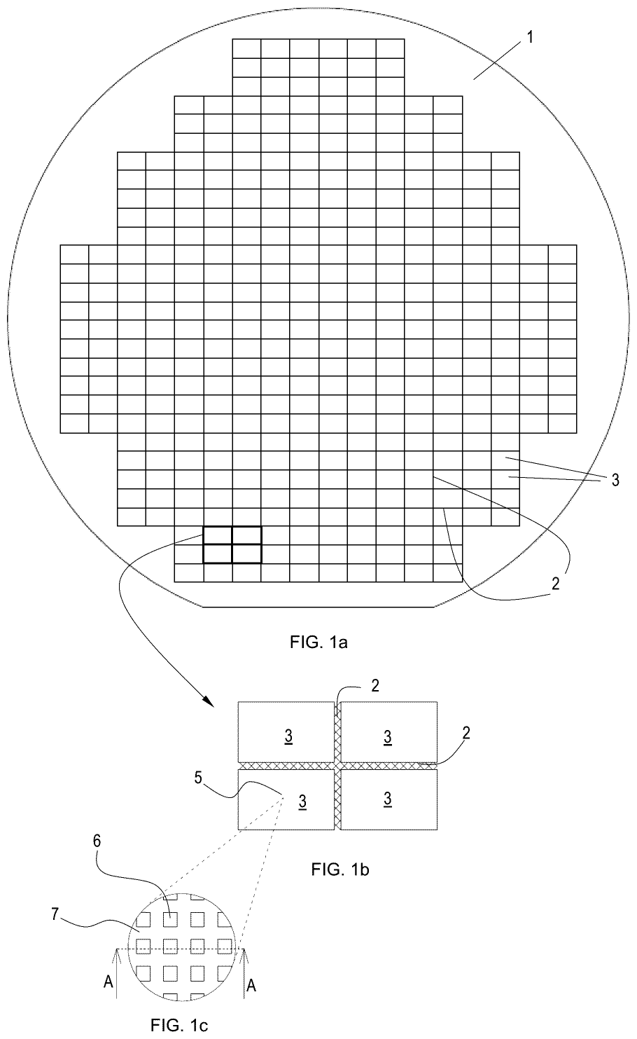

FIG. 1a illustrates a process wafer 1 which may be a crystalline silicon wafer as generally known in the art, for example a standard process wafer of 300 mm in diameter and having a thickness of a few hundred micrometers. Scribe lines 2 divide the wafer surface into a plurality of die areas on the front side of the wafer, hereafter also referred to as the die side of the wafer. Each die area includes a semiconductor die 3, which may be an integrated circuit produced according to a given processing sequence, and including contacts on its upper surface for electrically connecting the integrated circuit. Four adjacent dies 3 are represented in an enlarged image in FIG. 1b. The surface area of each die 3 may be in the order of a few tens of square mm. Details of the front surface of the dies 3 are not shown as these details are not distinguishable on the scale of the image in FIG. 1b. The scribe lines 2 are wide enough to enable singulating the finished dies, and may serve also as areas for printing auxiliary features such as metrology marks.

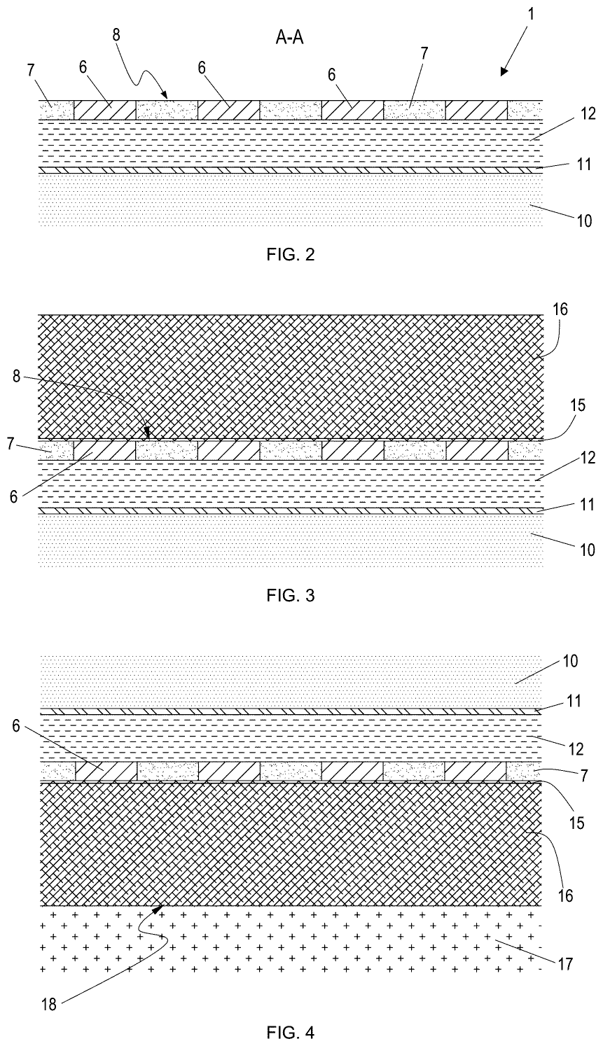

The method of the exemplary embodiment of the disclosure is explained on the basis of a micrometer-sized section along line A-A in one die 3, as indicated in FIG. 1c, which shows an enlargement of a spot 5 in the surface area of the die 3. In FIG. 1c, it is seen that the upper surface of the die is formed by an array of copper contact pads 6 embedded in a dielectric layer 7. The section view along line A-A is represented in a further enlarged view in FIG. 2. A thin upper portion of the wafer 1 is shown, the portion having a thickness in the order of a few micrometers.

As seen in FIG. 2, the die 3 is an integrated circuit die including a bulk Si part 10, a front end of line (FEOL) part 11 including active devices such as transistors or diodes, and a back end of line (BEOL) part 12 which is a multilevel structure of interconnected electrical conductors and vias designed to provide signal routing to the active devices, and embedded in an electrically isolating dielectric material. The Cu contact pads 6 and the dielectric layer 7 are lying on top of the BEOL part 12, with the contact pads 6 electrically connected to the top level of the BEOL part. The dielectric layer 7 is hereafter considered to be a layer of SiCN although other materials are possible, such as silicon oxide. Layer 7 is coplanar with the top surface of the Cu contact pads 6. The coplanar surface of the pads 6 and the layer 7 is referred to hereafter as the bonding surface 8 of the die 3.

In the plane of the wafer 1, the pads 6 have a rectangular cross-section with a width of about 2 μm. The thickness of the pads 6 is less than 1 μm. The distance between adjacent contact pads 6 is of the same order of magnitude as the width of the pads 6. As stated, these shapes and dimensions do not limit the scope of the disclosure, but are used as examples only.

The pads 6 may be processed by the damascene-type processing technique used for producing BEOL type interconnect structures. Usually, a diffusion barrier (not shown in FIG. 2) is present between the contact pads 6 and the dielectric layer 7.

The bonding surface 8 is intended to be bonded to a similar bonding surface of another die by a bonding technique known as hybrid bonding, wherein a direct Cu—Cu bond is formed between corresponding Cu contacts and wherein a direct SiCN—SiCN bond is formed between the respective SiCN layers. Before executing this bonding step, however, further processing steps are performed, which include thinning the bulk Si wafer 10 from the back side. To this aim, a layer of temporary bonding material (TBM) is to be coated on the die side of the wafer 1. According to the disclosure, and as illustrated in FIG. 3, the TBM layer is not deposited directly on the bonding surface 8, but an auxiliary layer 15 is deposited first on the bonding surface, followed by the deposition of the TBM layer 16. The TBM layer is typically an organic polymer layer capable of forming a (e.g., strong) temporary bond and removable by a solvent. Elastomers or thermoplastic polymers are suitable materials for this purpose. The thickness of the TBM layer 16 in the exemplary embodiment shown is about 4 μm. Generally this layer may be for example between 1 μm and 100 μm thick. The TBM layer may be applied by spin coating the polymer material onto the auxiliary layer 15.

According to the disclosure, the auxiliary layer is formed of a nitride or a carbide of a transition metal. The auxiliary layer 15 may be a layer of TiN for example, but other materials are applicable when applied to a dielectric or hybrid bonding surface, such as a hybrid Cu/SiCN surface. Besides titanium nitride, other (e.g., preferred) materials may include hafnium nitride, molybdenum nitride, tungsten nitride and tungsten carbide. These materials are removable from the hybrid surface such as a Cu/SiCN surface, without substantially attacking the constituent materials of the hybrid surface, e.g. without increasing the roughness of the dielectric bonding parts of a hybrid bonding layer and without oxidization of metal bonding pads in the hybrid bonding layer. These materials are also applicable on a dielectric bonding layer for direct dielectric-to-dielectric bonding. The auxiliary layer 15 may be applied for example by sputter deposition, which is a form of physical vapour deposition (PVD). The thickness of the auxiliary layer 15 may be a few tens of nanometers, which may be between 5 nm and 100 nm.

After applying the stack of layers 15 and 16, the wafer 1 is reversed and bonded face down to a temporary carrier wafer 17, as illustrated in FIG. 4, with the TBM layer 16 realizing a temporary adhesive bond along bonding interface 18.

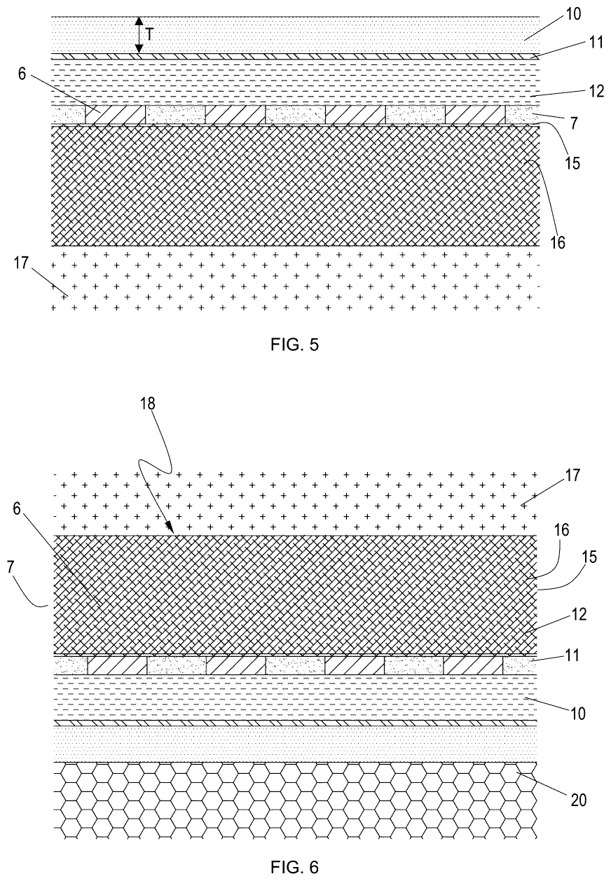

The bulk Si wafer 10 is then thinned from the back side, which may be done by grinding and/or wet etching, until the bulk Si is reduced to a thickness T as shown FIG. 5.

With reference to FIG. 6, the assembly of the carrier 17 and the process wafer 1 is then reversed and the back side of the thinned Si wafer 10 is bonded to an additional carrier 20 which may be an additional temporary carrier or a permanent carrier, e.g. a carrier to which the thinned wafer is bonded by a non-releasable bond or adhesive. Alternatively, the back side of the Si wafer 10 may be further thinned and subjected to processing steps, for example including the production of through-silicon vias and back side contacts.

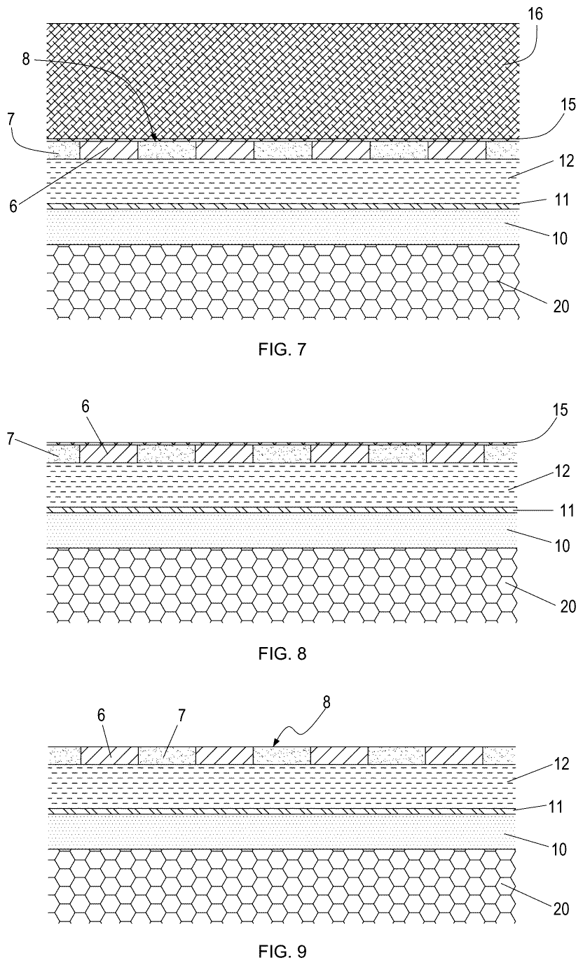

The temporary carrier 17 is then removed by releasing the temporary bond along interface 18, which may for example be done by heating if the TBM layer 16 is formed of a thermoplastic polymer. As shown in FIG. 7, the stack of the auxiliary layer 15 and the TBM layer 16 remains on the hybrid bonding surface 8.

Thereafter and with reference to FIG. 8, the TBM layer 16 is removed (e.g., selectively) with respect to the underlying auxiliary layer 15. This may be done by a solvent, applied by a suitable technique, for example by submerging the wafer or a batch of wafers in a solvent bath for a given time. Alternatively, on a single wafer, the solvent may be spun onto the wafer surface followed by drying the wafer surface. Depending on the type of solvent and the time allowed for the dissolution of the TBM, residues of the temporary bonding material may or may not remain on the surface of the auxiliary layer 15 after this TBM removal step.

This is followed by the removal of the auxiliary layer 15 as illustrated in FIG. 9. In the case of a TiN layer, this may be done by a wet etching step using an aqueous mixture that does not attack Cu nor SiCN. Even with TBM residue remaining on the TiN layer 15, this leaves the hybrid bonding surface 8 clean and (e.g., essentially) free of residues without increasing the roughness of the dielectric and without oxidizing the metal. The same result is obtainable using other nitrides or carbides of transition metals such as molybdenum nitride or tungsten carbide.

The provision of the auxiliary layer 15 thereby enables removing the TBM layer 16 (e.g., essentially) without leaving any residue material and without (e.g., negatively) affecting the bonding surface. The hybrid bonding surface 8 is thereby (e.g., ideally) prepared for a hybrid bonding process to another die or wafer. This may be done in a wafer-to-wafer bonding process or in a die-to-wafer bonding process, after singulating the wafer 1 along the scribe lines 2.

The method is applicable to different types of surfaces from which a temporary polymer layer needs to be removed without leaving residues. The method is for example applicable to a dielectric bonding surface as well as to a hybrid bonding surface, for example to a SiCN surface applicable in a direct SiCN—SiCN bonding process.

A practical example and proof of concept is described hereafter.

A TiN layer of 10 nm thick was deposited on a wafer having a SiCN blanket layer on its surface. The TiN deposition was carried out by sputter deposition. Thereafter a TBM layer of 30 μm thick was spun on the TiN layer. The TBM was BrewerBond® 305 available from supplier Brewer Science. The TBM layer was dissolved using the solvent mesitylene at 40° C. during a static dissolution time of 50 min. Thereafter, residues of the TBM material remained on the TiN surface. The TiN layer was removed by wet etching using an aqueous mixture at 55° C. during an etch time of 60s. After this, the TiN and the residues were completely removed, leaving a clean SiCN surface.

While the disclosure has been illustrated and described in detail in the drawings and foregoing description, such illustration and description are to be considered illustrative or exemplary and not restrictive. Other variations to the disclosed embodiments can be understood and effected by those skilled in the art in practicing the claimed disclosure, from a study of the drawings, the disclosure and the appended claims. In the claims, the word “including” does not exclude other elements or steps, and the indefinite article “a” or “an” does not exclude a plurality. The mere fact that certain measures are recited in mutually different dependent claims does not indicate that a combination of these measures cannot be used. Any reference signs in the claims should not be construed as limiting the scope.

What is claimed is:

1. A semiconductor processing method comprising:
providing a process wafer comprising a die side and a back side and comprising on the die side a plurality of dies which comprise a bonding surface suitable for dielectric-to-dielectric or hybrid bonding of the dies to a target substrate;
producing an auxiliary layer on the bonding surfaces of the dies;
producing a temporary bonding layer directly on the auxiliary layer;
temporarily bonding the process wafer to a carrier substrate by removably attaching the temporary bonding layer to the carrier substrate, performing processing steps on the back side of the process wafer, and releasing the process wafer from the carrier substrate such that the auxiliary layer and the temporary bonding layer remain on the die side of the process wafer;
removing the temporary bonding layer, selectively with respect to the auxiliary layer; and
removing the auxiliary layer, selectively with respect to the bonding surfaces, resulting in substantially residue-free bonding surfaces.

2. The method according to claim 1, wherein the bonding surfaces are suitable for direct dielectric-to-dielectric or hybrid bonding of the dies to the target substrate.

3. The method according to claim 1, wherein the auxiliary layer is formed of a nitride or a carbide of a transition material.

4. The method according to claim 3, wherein the auxiliary layer is formed of a material provided in the form of at least one of titanium nitride, hafnium nitride, tungsten nitride, molybdenum nitride, or tungsten carbide.

5. The method according to claim 1, wherein the bonding surfaces are suitable for hybrid bonding.

6. The method according to claim 1, wherein producing the auxiliary layer includes producing the auxiliary layer directly on the bonding surfaces of the dies.

7. The method according to claim 1, the bonding surfaces comprise metal contact pads embedded in a layer of dielectric material.

8. The method according to claim 7, wherein the metal contact pads are Cu contact pads.

9. The method according to claim 7, wherein the metal contact pads have a thickness of less than 1 μm.

10. The method according to claim 7, wherein a distance is provided between one or more metal contact pads, wherein the one or more metal contact pads are adjacent, and wherein the distance is about 2 μm.

11. The method according to claim 7, wherein the layer of dielectric material is a layer of SiCN.

12. The method according to claim 1, wherein the temporary bonding layer is an organic polymer layer.

13. The method according to claim 1, wherein the temporary bonding layer is provided in the form of elastomers or thermoplastic polymers.

14. The method according to claim 1, wherein the temporary bonding layer has a thickness of about 1 μm to about 100 μm.

15. The method according to claim 14, wherein the thickness of the temporary bonding layer is about 4 μm.

16. The method according to claim 1, wherein the temporary bonding layer is removed by applying a solvent to the bonding layer.

17. The method according to claim 1, wherein after removing the temporary bonding layer selectively with respect to the auxiliary layer, residues of the bonding layer remain on the auxiliary layer.

18. The method according to claim 1, wherein the auxiliary layer is removed by wet etching.

19. The method according to claim 1, wherein the auxiliary layer has a thickness between 5 nm and 100 nm.

20. The method according to claim 1, where the auxiliary layer is removable from the bonding surfaces without leaving residue on the bonding surfaces.
